(19) United States
(12) Patent Application Publication
(10) Pub. No.: US 2025/0048809 A1
(43) Pub. Date: Feb. 6, 2025

(54) DISPLAY APPARATUS FOR CONTROLLING VIEWING ANGLE

(71) Applicant: LG Display Co., Ltd., Seoul (KR)

(72) Inventor: YunSang KIM, Paju-si (KR)

(73) Assignee: LG Display Co., Ltd., Seoul (KR)

(21) Appl. No.: 18/791,010

(22) Filed: Jul. 31, 2024

(30) Foreign Application Priority Data
Jul. 31, 2023 (KR) 10-2023-0099501

(51) Int. Cl. H01L 33/58; B60K 35/65; H01L 25/16

(52) U.S. Cl. CPC H01L 33/58; B60K 35/656; H01L 25/167; B60K 2360/332

(57) ABSTRACT

A display device can include a light emitting package disposed in a first area on a substrate, where the light emitting package includes at least one first light emitting unit and a plurality of second light emitting units. The display device further includes at least one third light emitting unit disposed in a second area being adjacent to the first area, and a display panel disposed on the light emitting package and the at least one third light emitting unit. Each of the plurality of second light emitting units includes a light emitting chip and a light control unit disposed on the light emitting chip. Further, the light control unit is configured to change a path of light emitted from the light emitting chip.

### CROSS-REFERENCE TO RELATED APPLICATIONS

This application claims priority to Korean Patent Application No. 10-2023-0099501 filed in the Republic of Korea on Jul. 31, 2023, the entire contents of which is hereby expressly incorporated by reference into the present application.

### BACKGROUND

### Field of the Invention

The present disclosure relates to a display apparatus for controlling a viewing angle.

### Discussion of the Related Art

As the information society develops, various types of display devices have been developed. Among such various display devices, a liquid crystal display (LCD), a plasma display panel (PDP), and an organic light emitting display (OLED) have been used.

Generally, a display device does not necessarily limit a viewing angle for users. However, in some applications and situations such as for privacy and information protection purposes, a limitation of the viewing angle of the display device may be helpful or needed.

For example, in the case of the display device being used as an information medium inside a vehicle or the like, a high-definition image can be provided to a passenger (non-driver) in the passenger seat so that the passenger in the passenger seat can enjoy viewing the content displayed or provided by the display device.

However, to the driver of the same vehicle, such displayed content may be a distraction or undesirable, which can be a safety concern for the driver who needs to focus on driving. As such, there is a need to provide a display device which has a limited or controllable viewing angle to the driver of the vehicle.

### SUMMARY OF THE DISCLOSURE

The present disclosure has been made in view of the above problems and other limitations associated with the related art. However, the problems are not limited to the above-mentioned problems, and other technical problems and issues can be inferred from the related art.

Accordingly, it is an object of the present disclosure to provide a display device that can effectively limit a viewing angle, e.g., for a driver of a vehicle containing the display device.

In accordance with an aspect of the present disclosure, the above and other objects can be accomplished by the provision of a display device comprising a substrate, a light emitting package disposed in a first area on the substrate and including at least one first light emitting unit and a plurality of second light emitting units, at least one third light emitting unit disposed in a second area on the substrate, and a display panel disposed on the light emitting package and the at least one third light emitting unit, wherein the plurality of second light emitting units include a light emitting chip and a light control unit disposed on the light emitting chip.

Specific matters of other embodiments are included in the detailed description and drawings.

These and other objects of the present application will become more readily apparent from the detailed description given hereinafter. However, it should be understood that the detailed description and specific examples, while indicating various embodiments of the present disclosure, are given by way of illustration only, since various changes and modifications within the spirit and scope of the present disclosure will become apparent to those skilled in the art from this detailed description.

### BRIEF DESCRIPTION OF THE DRAWINGS

The present disclosure will become more fully understood from the detailed description given hereinbelow and the accompanying drawings which are given by way of illustration only, and thus are not limitative of the present disclosure.

FIG. 1 illustrates an example of a display device according to an embodiment of the present disclosure.

FIGS. 2A and 2B illustrate examples of implementations of a display device according to an embodiment of the present disclosure.

FIG. 3 illustrates an exploded perspective view of a display device according to an embodiment of the present disclosure.

FIG. 4 illustrates an arrangement of light emitting units included in a display device according to an embodiment of the present disclosure.

FIG. 5 illustrates an example of a cross sectional view along line A-A′ of FIG. 4.

FIG. 6 illustrates an example of a cross sectional view along line B-B′ of FIG. 4.

FIG. 7 is a diagram illustrating a first light emitting unit or a third light emitting unit of a display device according to an embodiment of the present disclosure.

FIG. 8 illustrates an example of a cross sectional view along line of C-C′ of FIG. 7.

FIGS. 9 to 13 illustrate examples of a second light emitting unit of a display device according to an embodiment of the present disclosure.

FIGS. 14A, 14B, and 14C illustrate examples of a louver of a display device according to an embodiment of the present disclosure.

FIG. 15 illustrates an arrangement of light emitting units included in a display device according to another embodiment of the present disclosure.

### DETAILED DESCRIPTION OF THE EMBODIMENTS OF THE DISCLOSURE

The terms used in the embodiments of the present disclosure have been selected as general terms that are currently widely used as possible in consideration of the functions of the present disclosure, but this can vary depending on the intention or precedent of a technician engaged in the field, the emergence of a new technology, and the like. In certain cases, there are terms arbitrarily selected by the applicant, and in this case, the meaning will be described in detail in the applicable description. Therefore, the terms used in this specification should be defined based on the meaning of the term and the overall content of this disclosure, not just the name of the term.

When a part of the specification “includes,” “comprises,” “has,”, etc. a component, it means that it can further include other components rather than excluding them unless otherwise stated.

The expression “at least one of a, b, and c” described throughout the specification can include ‘a alone’, ‘b alone’, ‘c alone’, ‘a and b’, ‘a and c’, ‘b and c’, or ‘a, b, and c’, or ‘a, b, and c all’. The advantages and features of the present disclosure, and methods of achieving them, will become apparent with reference to embodiments described in detail with reference to the accompanying drawings.

Since the shapes, areas, ratios, angles, numbers, etc. disclosed in the drawings for describing embodiments in the present disclosure are illustrative, the embodiments of the present disclosure are not limited to the illustrative matters. In describing embodiments, if it is determined that the detailed description of related known techniques can unnecessarily obscure the gist of embodiments, the detailed description thereof will be omitted or may be briefly provided.

If ‘including’, ‘having’, ‘being achieved’, or the like mentioned in the present disclosure are used, other parts can be added. In the case of expressing a component in singular, it includes the case of including a plurality unless otherwise explicitly stated. In addition, in interpreting a component, it is interpreted that the error range is included even if there is no separate explicit description.

In the case of a description of the positional relationship, for example, if the positional relationship of two parts is described as “on”, “above”, “over”, “below”, “on the side”, etc., one or more other parts can be located between the two parts. What an element or layer is referred to as “on another element” or “on a layer” includes all cases where another layer or another element is interposed just above or in the middle of the other element.

When an element or layer is disposed on (or above or over) another element or on another layer, the element or layer is disposed directly on the other element. Alternatively, the above case includes all cases in which another layer or another device is disposed between the element or layer and the other element.

In addition, terms such as first, second, and the like are used to describe various components, but these components are not limited by these terms. These terms are only used to distinguish one component from another component and may not define order or sequence. Thus, the first component mentioned below can be the second component within the technical idea of the present disclosure

Features of each of the various embodiments of the present disclosure can be partially or entirely combined or combined with each other, can be technically interlocked and driven in various ways, and each embodiment can be performed independently of each other or can be performed together in a related relationship.

In addition, the terms described later are defined in consideration of the functions in the implementation of this specification, and can vary depending on the intention or custom of the user or operator. Therefore, the definition should be made based on the content throughout this specification.

Further, the term “can” encompasses all the meanings and coverages of the term “may.” The term “disclosure” is interchangeably used with, or encompasses all the meanings and coverages of, the term “invention.” In addition, the term “vehicle” includes a general meaning of a vehicle or any other transportation means, and can be, e.g., an automobile, an airplane, a cart, a ship, a boat, a motorcycle, etc.

Hereinafter, embodiments of the present disclosure will be described centering on an organic light emitting display device. However, embodiments of the present disclosure are not limited to an organic light emitting display device, and can be applied to various electroluminescent displays. For example, the electroluminescent display device can be an organic light emitting diode display device, a quantum-dot light emitting diode display device, or an inorganic light emitting diode display device. Regardless, all the components of each display device or apparatus according to all embodiments of the present disclosure are operatively coupled and configured.

Hereinafter, embodiments of the present disclosure will be described with reference to the drawings.

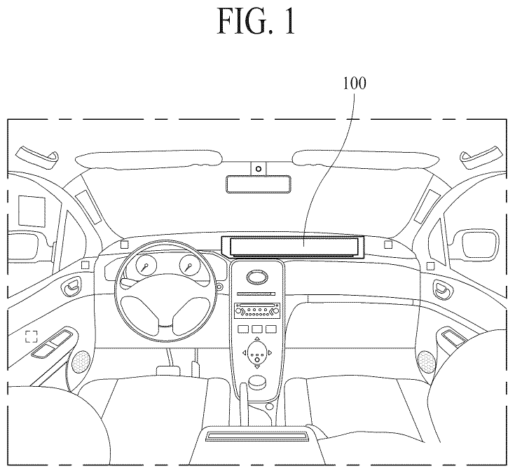

FIG. 1 illustrates an example of a display device according to an embodiment of the present disclosure.

Referring to FIG. 1, in an embodiment, a display device 100 can be disposed on at least a part of a dash board of a vehicle or another part of the vehicle. The display device 100 can be disposed to cross or near a driver's seat and a passenger seat disposed in a front seat of the vehicle, and can be disposed in front of the front seat. In this case, a user of the display device 100 can include the driver in the driver's seat and/or the passenger in the passenger seat. For example, both the driver and the passenger of the vehicle can use the display device 100.

Also, the dashboard of the vehicle or the display device 100 can further include an input configuration for manipulating all various functions related to an interior and operation of the vehicle. For example, the dashboard or the display device 100 can manipulate an air conditioner or a climate control system, an audio system, a navigation system, a smart phone system, a vehicle enhancement system, and the like.

The display device 100 can provide a variety of information related to the vehicle. For example, the display device 100 can provide vehicle driving information such as a current speed of the vehicle, a remaining fuel amount, and a driving distance. Also, the display device 100 can provide information on vehicle components such as a degree of damage to a vehicle tire.

In an embodiment, FIG. 1 can illustrate a part of the display device 100. For example, the display device 100 can indicate a part corresponding to the display panel among various components included in the display device 100. For instance, the display device 100 can represent at least a part of a display area and a non-display area of the display panel. In addition, among the components of the display device 100, components other than those illustrated in FIG. 1 can be mounted inside the vehicle.

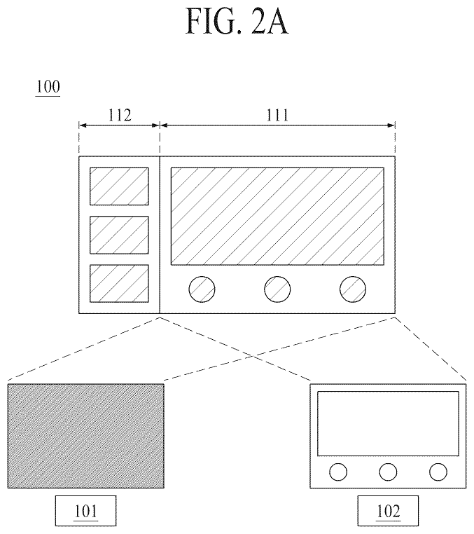

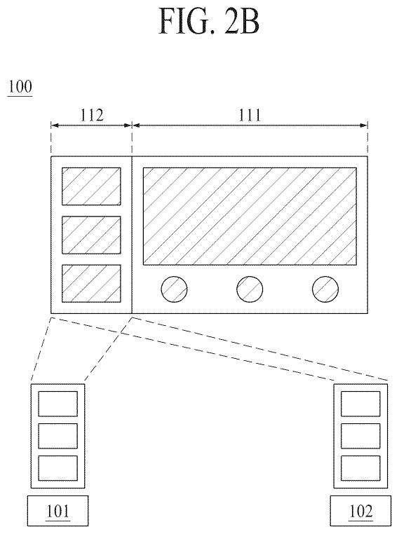

FIGS. 2A and 2B illustrate examples of implementations of a display device according to an embodiment of the present disclosure.

Particularly, FIG. 2A illustrates a case where a first area 111 of the display device 100 operates in a viewing angle limit mode. The viewing angle limit mode can refer to a mode in which a viewing angle is limited to provide light in a specific direction. However, the present disclosure is not limited thereto, and can be referred to in various terms according to embodiments.

Referring to FIG. 2A, it shows an example of a screen of the display device 100 that can be visually recognized by both a driver 101 in the driver's seat of the vehicle and a passenger 102 in the passenger's seat of the vehicle where the viewing angle is limited (or restricted) in the first area 111 of the display device 100. As such, the passenger 102 can see the entire content displayed in the first area 111. However, since the viewing angle of the first area 111 is limited, the driver 101 cannot see the content displayed in the first area 111. In this case, as shown, the driver 101 in the driver's seat can see a black screen where contents are blocked from being displaying, and is not able to see the contents of the first area 111 that are visible and viewable by the passenger 102 in the passenger's seat.

FIG. 2B illustrates a case where a second area 112 of the display device 100 operates in a normal mode. The normal mode can mean a mode in which the viewing angle is not limited (e.g., restricted), so that all users around the display device 100 can see the screen displayed on the display device. However, the present disclosure is not limited thereto and can be referred to in various terms according to embodiments.

Referring to FIG. 2B, the second area 112 of the display device 100 operates in a general mode or a normal mode in which the viewing angle is not limited (e.g., restricted). In that mode, both the driver 101 and the passenger 102 can see the same content fully that is displayed in the second area 112 of the display device 100.

The first area 111 and the second area 112 can also be referred to as a first region 111 and a second region 112, respectively.

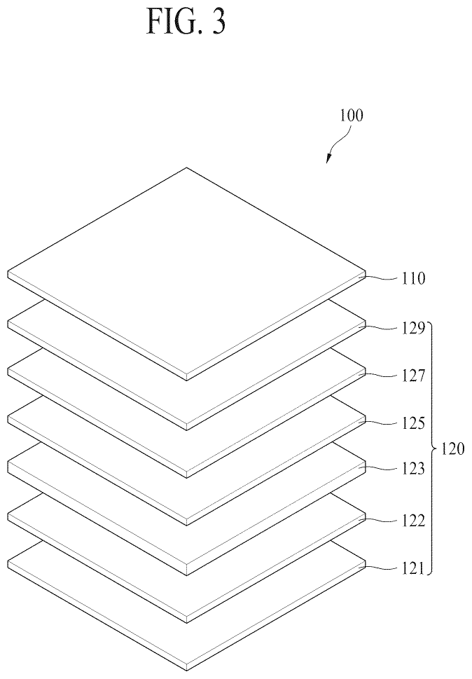

FIG. 3 illustrates an exploded perspective view of a display device according to an embodiment of the present disclosure.

Referring to FIG. 3, the display device 100 can include a display panel 110 for displaying an image and a backlight unit 120 disposed on a rear surface of the display panel 110 to emit light to a front surface of the display panel 110.

The display panel 110 can be disposed on the backlight unit 120. The display panel 110 can include a color filter and at least one thin film transistor (TFT). The display panel 110 can include a liquid crystal panel. The display panel 110 can include a lower substrate and an upper substrate bonded to face each other, and a liquid crystal layer disposed between the lower substrate and the upper substrate.

In an embodiment, the lower substrate can include gate lines and data lines arranged to cross each other, and liquid crystal cells formed in cross regions of the gate lines and data lines. In an embodiment, the liquid crystal cells can be disposed in a matrix form (e.g., rows and columns) or other configuration on the lower substrate. The liquid crystal cells can include a thin film transistor disposed in intersection regions of gate lines and data lines, and a pixel electrode that receives a data voltage applied to the data line through the thin film transistor when the thin film transistor is turned on.

In an embodiment, the color filters for realizing multiple colors, including red, green, and blue, a black matrix (BM) for partitioning the color filters and disposed between the color filters and for blocking light passing through the liquid crystal layer, and a common electrode for applying a voltage to the liquid crystal layer can be formed on the upper substrate.

In an embodiment, a common electrode can be formed on the upper substrate in a vertical electric field driving method such as a twisted nematic (TN) mode and a vertical alignment (VA) mode, and can be formed on the lower substrate together with a pixel electrode in a horizontal electric field driving method such as an IPS (In-Plane Switching) mode and a FFS (Fringe Field Switching) mode.

In an embodiment, the liquid crystal cells are driven according to an electric field generated by a potential difference between a data voltage supplied to a pixel electrode through the data lines and a common voltage supplied to the common electrode to adjust the amount of light transmitted from the display panel 110.

The backlight unit 120 can be disposed below the display panel 110. The backlight unit 120 generates light and can provide the light to the display panel 110. The backlight unit 120 can include a cover bottom 121, a substrate 122, a light emitting package layer 123, a diffuser layer (or diffusion layer or diffusion plate) 125, a prism layer (or a prism sheet) 127 and a light emitting control film (or polarizing layer) 129.

The cover bottom 121 can accommodate and fix at least some components of the display panel 110 and the backlight unit 120. According to an embodiment, the display device 100 or the backlight unit 120 can further include a mechanical component, such as a panel guide and/or a top case, to accommodate and fix the components of the backlight unit 120.

The substrate 122 can include a plurality of circuits and a printed circuit board (PCBs).

The light emitting package layer 123 can be driven by receiving power from the outside (e.g., an external source), and can generate light. The light emitting package layer 123 can generate light using various light sources such as a cold cathode fluorescent lamp (CCFL), an external electrode fluorescent lamp (EEFL), a hot cathode fluorescent lamp (HCFL), and a light emitting diode (LED).

The light emitting package layer 123 can include a plurality of light emitting units. The plurality of light emitting units can include, for example, at least one first light emitting unit, a plurality of second light emitting units, and at least one third light emitting unit. The first light emitting unit and the third light emitting unit can be the same type of light emitting unit, and the second light emitting unit can be a type of light emitting unit that is distinguished from or different from the first light emitting unit or the third light emitting unit. A more detailed description thereof will be described later.

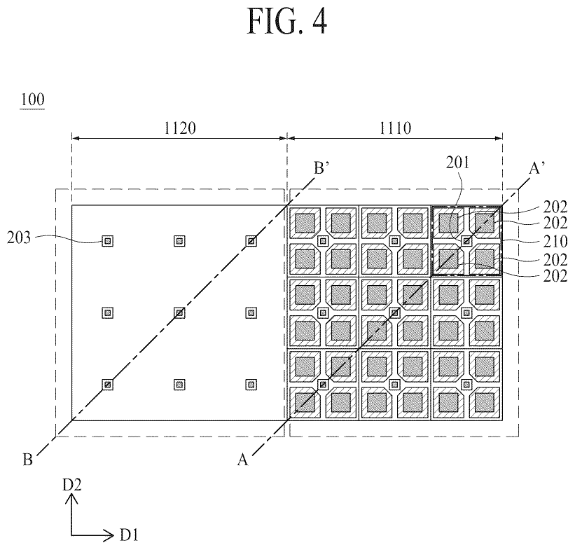

According to an embodiment, the light emitting package layer 123 can be divided into a plurality of regions. For example, the light emitting package layer 123 can be divided into a first region and a second region. The at least one first light emitting unit and the plurality of second light emitting units can be disposed in the first region. The at least one third light emitting unit can be disposed in the second region. A more detailed example of the planar arrangement of the light emitting units in the first region and the second region of the light emitting package layer 123 will be described later with reference to FIG. 4.

The diffuser layer 125 diffuses the light emitted from the light emitting package layer 123, thereby improving uniformity of luminance according to the viewing angle of the display device 100. The diffuser layer 125 can be formed in the form of a plate with more than a predetermined hardness, or can be formed in the form of a sheet with less than a predetermined hardness. Also, the diffuser layer 125 can include at least one of a polycarbonate resin, an acrylic resin, a polyurethane, a polyester, a fluorine resin, a silicon resin, a polyamideimide, an epoxy resin, and an ultraviolet curable resin. Also, a light diffusion material can be distributed in the diffuser layer 125. The light diffusion material can include at least one of titanium oxide, zinc oxide, barium sulfate, calcium carbonate, magnesium carbonate, aluminum hydroxide, and clay. Also, resin beads can be distributed in the diffusion layer 125. The resin beads can include at least one of an acrylic resin, an acrylonitrile resin, a polyurethane, a polyvinyl chloride, polystyrene, polyacrylonitrile, and a polyamide.

The prism layer 127 improves the front luminance of the display panel 110 by controlling the direction of the light passing through the diffuser layer 125. For example, the prism layer 127 can include an upper prism sheet and a lower prism sheet in which prism patterns are formed and axes of the prism patterns are arranged orthogonal to each other. The prism layer 127 can be configured in the form of a sheet with less than a predetermined hardness. The prism layer 127 can be formed of a transparent material to pass light. For example, the prism layer 127 can include at least one of an acrylic resin, polyurethane, polyester, fluorine resin, silicon resin, polyamideimide, epoxy resin, and ultraviolet curable resin.

In an embodiment, the prism layer 127 can be formed of polyethylene terephthalate (PET). In some cases, the prism layer 127 can include at least two or more layers, but is not limited thereto and can be composed of one layer.

The polarizing layer 129 can be a reflective polarizing layer. For example, the polarizing layer 129 can have a structure in which a left circularly polarizing layer and a right circularly polarizing layer are alternately stacked, and the luminance can be improved by such a structure. In the polarizing layer 129, light in the same direction as the polarization direction is transmitted. In addition, light in a direction different from the polarization direction passes through the polarizing layer 129 by changing the traveling direction by the reflector. Above the polarizing layer 129 can be classified into a reflective polarizing layer, and since there is no loss of light compared to an absorption type polarizing layer, luminance can be improved. However, the configuration of the present disclosure is not limited thereto, and a polarizing layer having a different function can be applied. The polarizing layer 129 can be referred to as a double brightness enhancement film (DBEF) according to the configuration, but is not limited thereto.

According to an embodiment, the display device 100 can further include an optical film such as a light control film (LCF). However, the present disclosure is not limited thereto.

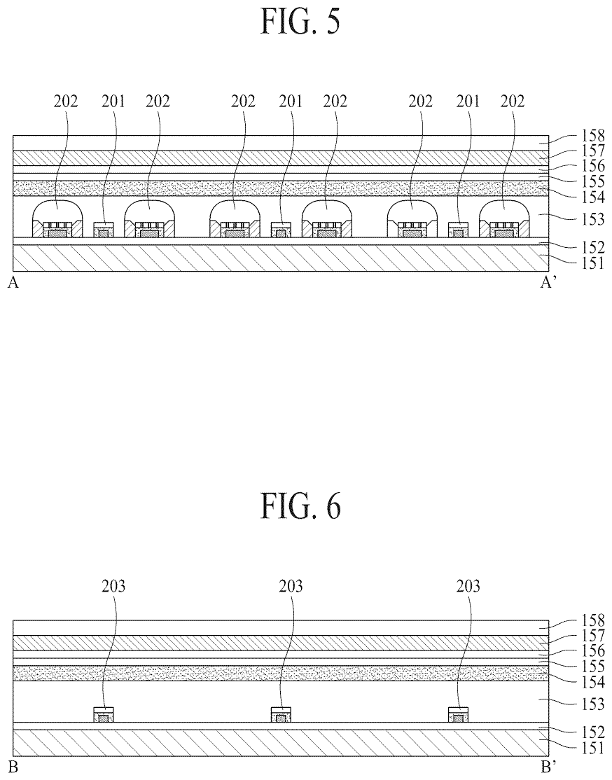

FIG. 4 illustrates an arrangement of light emitting units included in a display device according to an embodiment of the present disclosure. FIG. 5 illustrates an example of a cross sectional view along line A-A′ of FIG. 4. FIG. 6 illustrates an example of a cross sectional view along line B-B′ of FIG. 4. Hereinafter, FIGS. 4 to 6 will be described together.

Referring to FIG. 4, the display device 100 in this embodiment can include a first region 1110 and a second region 1120, which can be part of a screen configured to display contents. The first region 1110 can include a region which can be driven in a viewing angle limit mode or a normal mode. The second region 1120 can include a region which can be driven in the normal mode.

The first region 1110 can include a plurality of light emitting packages 210. The plurality of light emitting packages 210 can be arranged to have a plurality of columns and a plurality of rows along a first direction D1 and a second direction D2, e.g., in a matrix configuration.

Each light emitting package 210 can include at least one first light emitting unit 201 and at least one second light emitting unit 202. For example, at least one first light emitting unit 201 and a plurality of second light emitting units 202 can be disposed in each light emitting package 210. In the example of FIG. 4, each light emitting package 210 can include one first light emitting unit 201 and four second light emitting units 202 adjacent to the first light emitting unit 201.

The plurality of second light emitting units 202 can be arranged to surround the at least one first light emitting unit 201. For example, the plurality of second light emitting units 202 are arranged around the first light emitting unit 201, and the plurality of second light emitting units 202 can be spaced apart from the first light emitting unit 201 by a predetermined interval.

In the example of FIG. 4, each of the four second light emitting units 202 surrounding one first light emitting unit 201 can be a 2-1th light emitting unit, a 2-2th light emitting unit, a 2-3th light emitting unit, and a 2-4th light emitting unit. Also, the at least one first light emitting unit can include a 1-1th light emitting unit. In this case, the plurality of second light emitting units can be arranged around the 1-1th light emitting unit, and the plurality of second light emitting units can be spaced apart from the 1-1th light emitting unit by a predetermined interval. Alternatively, the 2-1th light emitting unit, the 2-2th light emitting unit, the 2-3th light emitting unit, and the 2-4th light emitting unit can be arranged around the 1-1th light emitting unit, and the light emitting packages 210 can be arranged adjacent to each other in the first region 1110.

The second region 1120 can include a plurality of third light emitting units 203. In the example of FIG. 4, the plurality of third light emitting units 203 can be arranged to have a plurality of columns and a plurality of rows along the first and second directions D1, D2, e.g., in a matrix configuration.

In an embodiment, each third light emitting unit 203 can have the same configuration as the first light emitting unit 201 so that the first and third light emitting units 201 and 203 can have the same configurations but are placed at different locations such as the first and second regions 1110 and 1120. In this case, the third light emitting unit 203 can be a term referring to the first light emitting unit 201 disposed in the second region 1120. However, the present disclosure is not limited thereto, and according to an embodiment, the third light emitting unit 203 can be implemented in a configuration that is different from the first light emitting unit 201.

In an embodiment, the third light emitting unit 203 can be disposed in the second region 1120 to correspond to the arrangement of the first light emitting unit 201 in the first region 1110. For example, the spacing and arrangement between the third light emitting units 203 in the second region 1120 can coincide with (or can be the same as) the spacing and arrangement between the first light emitting units 201 in the first region 1110. For another example, the first light emitting unit 201 or the third light emitting unit 203 can be disposed in the first region 1110 and the second region 1120 at regular intervals. In this case, the second light emitting unit 202 can be disposed around the first light emitting unit 201 in the first region 1110, and the arrangement of the second light emitting unit 202 can be omitted in the second region 1120.

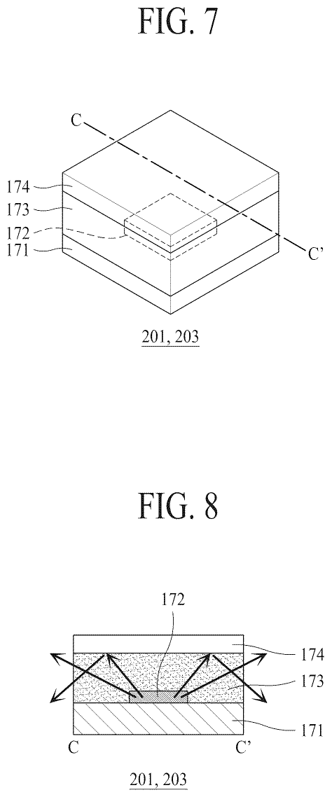

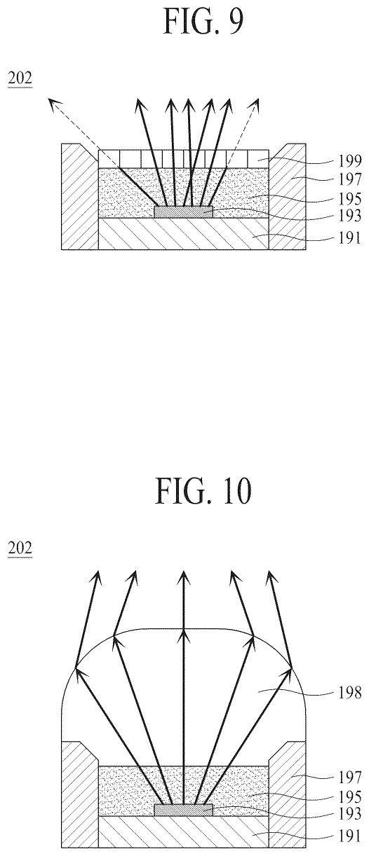

In an embodiment, the first light emitting unit 201 and the third light emitting unit 203 can be light emitting units that do not limit or restrict a viewing angle. Examples of the first light emitting unit 201 and the third light emitting unit 203 can be referred to FIGS. 7 and 8. The second light emitting unit 202 can be the light emitting unit that limits (e.g., restricts) a viewing angle, so that contents displayed in the first region 1110 can be selectively viewable by a specific user (e.g., only the passenger, but not the driver in a vehicle). An example of the second light emitting unit 202 can be referred to FIGS. 9 to 11. These examples will be discussed later in more detail.

FIG. 5 illustrates an example of a cross sectional view along line A-A′ of FIG. 4. In this case, the A-A′ line can be a line that crosses the first light emitting unit 201 in the first region 1110 of the display device, and also crosses the second light emitting unit 202 disposed on one side of the first light emitting unit 201 and the second light emitting unit 202 disposed on the other side of the first light emitting unit 201. These second light emitting units 202 can be disposed at opposite sides of the first light emitting unit 201.

Referring to FIG. 5, the first region 1110 can include a cover bottom 151, a substrate 152, a light emitting package layer 153, a diffusion layer 154, a prism layer 155, and a display panel 157.

The cover bottom 151 can correspond to the cover bottom 121 shown in FIG. 3. The cover bottom 151 can accommodate and fix at least one component disposed on the cover bottom 151

The substrate 152 corresponds to the substrate 122 shown in the example of FIG. 3, and can be disposed on the cover bottom 151. The substrate 152 can include a plurality of circuits and a printed circuit board.

The light emitting package layer 153 can correspond to the light emitting package layer 123 shown in the example of FIG. 3, and can be disposed on the substrate 152. The light emitting package layer 153 can include a plurality of light emitting units, and the plurality of light emitting units can be driven by being connected to the printed circuit board.

In an embodiment, the first light emitting unit 201 and the second light emitting unit 202 can be disposed in the light emitting package layer 153. The first light emitting unit 201 can be disposed between the second light emitting units 202. As shown in the example of FIG. 5, one first light emitting unit 201 can be disposed between two second light emitting units 202. Also, the distance between the first light emitting unit 201 and each of the two second light emitting units 202 can be constant or same.

In an embodiment, each first light emitting unit 201 can include at least one of a frame, a light emitting chip, a filling layer, and a reflective layer. Also, each second light emitting unit 202 can include at least one of a frame, a light emitting chip, a filling layer, a partition wall, and a light control unit. The light control unit can include at least one of a louver (e.g., shutter or shuttered shaped) and a lens, or can be represented by an opening (e.g., opening 194 in FIG. 12). The configuration of each first light emitting unit 201 will be described later in detail in one example of FIGS. 7 and 8 below, and the configuration of each second light emitting unit 202 will be described later in detail in various examples of FIGS. 9 to 13.

Referring back to FIG. 4, the first light emitting unit 201 and a plurality of second light emitting units 202 disposed around the first light emitting unit 201 can be referred to as light emitting packages. For example, referring to FIG. 4 together, the light emitting package can include the first light emitting unit 201 and four second light emitting units 202 disposed around the first light emitting unit 201.

Referring to FIG. 5, in an embodiment, the light emitting package can be configured as one set. For example, the light emitting package can be disposed on a separate substrate and can exist as a separate configuration. In this case, the light emitting package layer 153 can be provided by a combination of a plurality of light emitting packages.

The diffuser layer 154 can correspond to the diffuser layer 124 shown in FIG. 3, and can be disposed on the light emitting package layer 153. The diffuser layer 154 can be formed in the form of a plate with more than a predetermined hardness, or can be formed in the form of a sheet with less than a predetermined hardness. Also, light diffusion materials and/or resin beads can be distributed in the diffuser layer 154. As a result, light incident on the diffuser layer 154 can be scattered so that the light can be effectively diffused.

The prism layer 155 corresponds to the prism layer 127 shown in FIG. 3, and can be disposed on the diffuser layer 154. The prism layer 155 can be configured in the form of a sheet with less than a predetermined hardness, and can have a thickness thinner than that of the diffusion layer 154. Also, the prism layer 155 can be more flexible than that of the diffusion layer 154.

The polarizing layer 156 can correspond to the polarizing layer 129 shown in FIG. 3, and can be disposed on the prism layer 155. The polarizing layer 156 can be formed in the form of a film. The polarizing layer 156 can be formed of a flexible and thin material, but is not limited thereto.

The display panel 157 corresponds to the display panel 110 illustrated in FIG. 3, and can be disposed on the polarizing layer 156. The display panel 157 can include a lower substrate and an upper substrate bonded to face each other, and a liquid crystal layer interposed between the lower substrate and the upper substrate. However, the present disclosure is not limited thereto.

In an embodiment, the prism layer 155 and the polarizing layer 156 can be formed to have the same thickness, but are not limited thereto. In some cases, the thickness of each of the prism layer 155 and the polarizing layer 156 can be equal to or less than 1/10 of the thickness of the diffusion layer 154.

In an embodiment, the display panel 157 can include gate lines and data lines arranged to cross each other, and liquid crystal cells formed in cross regions of the gate lines and data lines. The display panel 157 can include a plurality of transistors. The display panel 157 can include color filters for realizing a plurality of colors, including red, green, and blue, a black matrix for partitioning the color filters and blocking light passing through the liquid crystal layer, and a common electrode for applying a voltage to the liquid crystal layer can be formed. According to an embodiment, the display panel 157 can be referred to as a board assembly (B/A), but is not limited thereto.

A cover glass (or a cover window) 158 can be disposed on the display panel 157. The cover glass 158 can be formed of transparent glass, and can be formed to cover the display panel 157. The cover glass 158 can protect the display panel 157.

In FIGS. 5 and 6, the same or similar configurations are indicated by the same reference numerals, and hereinafter, content overlapping with the previously described content will be omitted or may be briefly provided.

Referring to FIG. 6, the third light emitting unit 203 can be disposed in the second region 1120. The third light emitting unit 203 can correspond to the first light emitting unit 201 of FIG. 5. For example, the third light emitting unit 203 and the first light emitting unit 201 can be the same device that have the same configuration. Also, in the second region 1120, the third light emitting units 203 can be disposed at regular intervals. The third light emitting units 203 in the second region 1120 are driven in the normal mode.

In an embodiment, an arrangement interval of the third light emitting units 203 can be the same as an arrangement interval of the first light emitting units 201 in the first region 1110. However, the present disclosure is not limited thereto, and an arrangement interval of the third light emitting units 203 can be narrower than an arrangement interval of the first light emitting units 201.

As such, the second region 1120 of FIG. 5 can be driven in the normal mode (non-viewing angle limit mode) by the operation of the third light emitting units 203. The first region 1110 of FIG. 5 can be driven in the normal mode by the operation of the first light emitting units 201 alone or with the second light emitting units 202, or can be driven in the viewing angle limit mode by the operation of the second light emitting units 202 alone.

FIG. 7 is a diagram illustrating a first light emitting unit or a third light emitting unit of a display device according to an example of the present disclosure. FIG. 8 illustrates an example of a cross sectional view along line of C-C′ of FIG. 7. In FIG. 8, the same configuration as in FIG. 7 is indicated by the same reference numerals. Hereinafter, FIGS. 7 and 8 will be described together.

Referring to FIGS. 7 and 8, the first light emitting unit 201 or the third light emitting unit 203 can have a hexahedral shape. The first light emitting unit 201 or the third light emitting unit 203 can include a frame 171, a light emitting chip 172, a filling layer 173, and a reflective layer 174.

The frame 171 can be disposed on a substrate of the display device to be electrically connected to a circuit formed on the substrate or other components connected to the substrate. The frame 171 can be made of a metallic material, but is not limited thereto.

The light emitting chip 172 can be disposed on at least a partial area of the frame 171. For example, as illustrated in the example of FIG. 8, the light emitting chip 172 can be disposed on a central area of the frame 171. The light emitting chip 172 can be configured to generate light. For example, the light emitting chip 172 can be connected to the circuit formed on the substrate to receive an electrical signal and can convert the electrical signal into light.

The filling layer 173 can be disposed around the light emitting chip 172. The filling layer 173 can be formed to cover the light emitting chip 172. Also, the filling layer 173 can be disposed on the periphery of the light emitting chip 172 and the remaining area on the frame 171 where the light emitting chip 172 is not disposed. The filling layer 173 can include a phosphor and a resin. The filling layer 173 can expand the light emission path to the left and right. For example, the filling layer 173 can expand the light emission path to the upper surface and the side surfaces of the light emitting chip 172. A direction angle, which is an angle at which light is emitted by the filling layer 173, can correspond to a range of 170° to 190°. For example, the direction angle by the filling layer 173 can be 180°.

The reflective layer 174 can be disposed on the filling layer 173. The reflective layer 174 can be formed of a material that reflects light, for example, a metal material. As the reflective layer 174 is disposed on the filling layer 173, light generated by the light emitting chip 172 can be emitted to a portion other than the portion where the reflective layer 174 is disposed. For example, light can be emitted to a side surface of the light emitting chip 172 as the reflective layer 174 is disposed on the light emitting chip 172. As a result, the light can emit and propagate from the sides of the first and third light emitting units 201 and 203, and the light emitted therefrom is directed towards the display panel 157 of the display device for a normal operation where, e.g., the viewing angle is not limited or restricted.

FIGS. 9 to 13 illustrate various examples of a second light emitting unit of a display device according to an embodiment of the present disclosure. Hereinafter, the same components as in FIGS. 7 and 8 are indicated by the same reference numerals in FIGS. 9 to 13, and overlapping contents for specific components can be omitted or may be briefly discussed. Here, FIGS. 9 to 13 illustrate different configurations of a cross section of the second light emitting unit as shown in FIG. 4.

In an embodiment, the second light emitting unit 202 can have a hexahedral shape like the first light emitting unit 201 of FIG. 7. For example, the second light emitting unit 202 according to an example of FIGS. 9 and 12 can have a hexahedral shape.

Referring to an example of FIG. 9, the second light emitting unit 202 of the display device can include a frame 191, a light emitting chip 193, a filling layer 195, a partition wall 197, and a louver 199. The frame 191 can be disposed on the substrate of the display device and electrically connected to the circuit formed on the substrate or other components connected to the substrate. The frame 191 can be formed of a metallic material, but is not limited thereto.

The light emitting chip 193 can be disposed on at least a partial area on the frame 191. For example, as illustrated in FIG. 9, the light emitting chip 193 can be disposed on a central area of the frame 191. The light emitting chip 193 can be configured to generate light. For example, the light emitting chip 193 can be connected to the circuit formed on the substrate to receive the electrical signal and can convert the electrical signal into light.

The filling layer 195 can be disposed around the light emitting chip 193. The filling layer 195 can be formed to cover the light emitting chip 193. Also, the filling layer 195 can be disposed on the periphery of the light emitting chip 193 and the remaining area on the frame 191, where the light emitting chip 193 is not disposed. The filling layer 195 can include a phosphor and a resin. The filling layer 195 can expand a light emission path. For example, the filling layer 195 can further expand the light emission path to the upper and side surfaces of the light emitting chip 193.

The louver 199 can be disposed on the filling layer 195. The louver 199 can include a plurality of blocking films and a plurality of cells separated by the plurality of blocking films. One side of the plurality of blocking films can be in contact with the filling layer 195, and the other side can be exposed to the outside. In addition, each of the plurality of blocking films can be formed to be spaced apart. In addition, the plurality of cells can be open at the top and bottom. For example, the inner area of the plurality of cells can be exposed to the outside. Accordingly, when the light passing through the filling layer 195 is incident to the lower side of the cell of the louver 199, the light can pass through the louver 199.

In an embodiment, the plurality of blocking films included in the louver 199 can be formed of a material that reflects light. In another embodiment, the plurality of blocking films included in the louver 199 can be formed of a material capable of blocking light, such as black resin or ink. The angle between the plurality of blocking films and the lower side of the louver 199 can be designated as a value in a range of −50° or more and +50° or less, e.g., range from −50° to +50° for example, the angle between the plurality of blocking films and the lower side of the louver 199 can have a value greater than 0° and equal to or less than +10°, but is not limited thereto.

Depending on the configuration, light has various directions and can be incident on the louver 199. Depending on the incident angle of light, some of the light is reflected by at least one of the plurality of cells, and the path of the light can be changed. For example, when the light has an incident angle between the light and the lower side of the plurality of cells where the incident angle is equal to or greater than a certain angle, the light can enter the louver 199. In this case, the incident light can contact the blocking film of the louver 199. Accordingly, the incident light is reflected by the blocking film and the path of light can be changed. Also, when the light has an incident angle formed by the light and the lower side of the plurality of cells less than a certain angle, the light can enter the louver 199. In this case, the incident light can pass through the louver 199 and proceed in an original path.

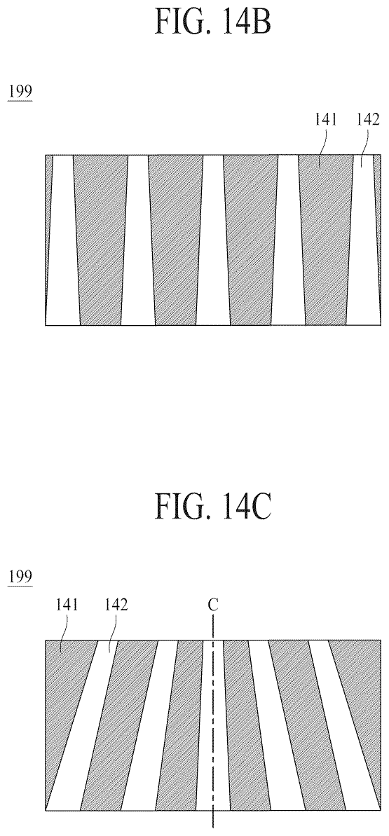

Each of the plurality of blocking layers of the louver 199 can have a predetermined angle with an upper surface of the light emitting chip 193 or an upper surface of the filling layer 195. According to an embodiment, angles formed by the blocking layer and the upper surface of the light emitting chip 193 or the upper surface of the filling layer 195 can be different for each of the plurality of blocking layers. For more specific examples related to the arrangement of the blocking layer, reference can be made to FIGS. 14A, 14B and 14C which will be discussed later in more detail.

Referring back to FIG. 9, the partition wall 197 can be surround at least a portion of the frame 191, the filling layer 195, and the louver 199. One side surface of the partition wall 197 can be implemented in a square shape, but is not limited thereto. Also, the height of the partition wall 197 can be greater than the sum of the heights of the frame 191, the filling layer 195, and the louver 199.

In an embodiment, the partition wall 197 can be formed of a material capable of reflecting light, for example, a metal material. In this case, light incident on the partition wall 197 through the filling layer 195 can be reflected to change the path of the light to the upper side where the louver 199 is disposed.

In an embodiment, at least a portion of an upper side of the partition 197 can be inclined to have an angle less than a certain angle with the louver 199 as illustrated. The angle of inclination of the partition 197 can be adjusted according to setting of the directional angle of the second light emitting unit 202. However, the present disclosure is not limited thereto, and the partition 197 can be implemented without inclination.

Referring to another example shown in FIG. 10, the second light emitting unit 202 can include a frame 191, a light emitting chip 193, a filling layer 195, a partition wall 197, and a lens 198. Since the frame 191, the light emitting chip 193, and the filling layer 195 of FIG. 10 are the same as those of FIG. 9, detailed descriptions thereof will be omitted or may be briefly provided. The same description as that of FIG. 9 can be omitted with respect to the partition wall 197.

The partition 197 of FIG. 10 can be surround the frame 191 and the filling layer 195. A plane of the partition 197 can be implemented in a square shape, but the present disclosure is not limited thereto.

In an embodiment, the partition wall 197 can be made of a material capable of reflecting light, for example, a metal material. In this case, light incident on the partition wall 197 through the filling layer 195 can be reflected and the path of the light can be changed to the upper side where the lens 198 is disposed.

The lens 198 can be disposed on the filling layer 195 and the partition wall 197. The lens 198 can have a convex shape toward the path of light, as illustrated. The path of light can be changed by the curved surface of the lens 198. For example, since the lens 198 has the convex shape, the light can have a specific directivity angle. For example, light can be focused in front of the display device by the lens 198, and a viewing angle of a surface can be limited.

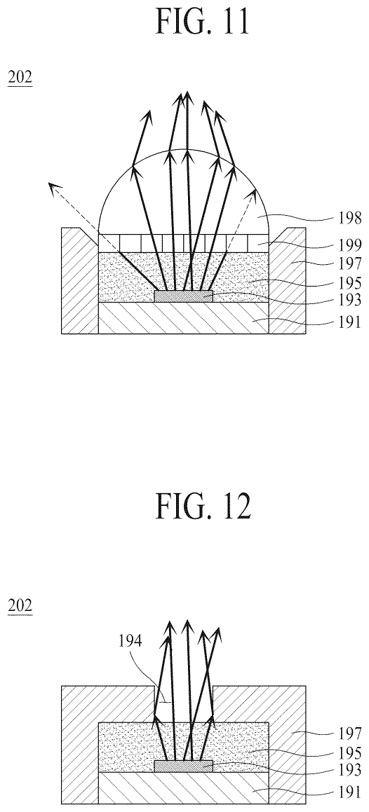

Referring to another example of FIG. 11, the second light emitting unit 202 can include a frame 191, a light emitting chip 193, a filling layer 195, a partition wall 197, a lens 198, and a louver 199. The frame 191, the light emitting chip 193, the filling layer 195, the partition wall 197, and the louver 199 are the same as those of FIG. 9, and thus a detailed description thereof will be omitted or may be briefly provided.

The lens 198 of FIG. 11 can be disposed on the louver 199. For example, as illustrated, the lens 198 can be disposed on an upper surface of the louver 199. The lens 198 can control the path of the light so that the light passing through the louver 199 is concentrated front of the display device. Accordingly, since the path of the light can be changed doubly through the lens 198 and the louver 199, condensing to the front of the display device can be more easily performed.

Referring to still another example of FIG. 12, the second light emitting unit 202 can include a frame 191, a light emitting chip 193, a filling layer 195, and a partition wall 197. The frame 191, the light emitting chip 193, and the filling layer 195 of FIG. 12 are the same as those of FIG. 9, and thus a detailed description thereof will be omitted or may be briefly provided. With respect to the partition 197, the same contents as those of FIG. 9 can be omitted or may be briefly provided.

The second light emitting unit 202 of FIG. 12 can include the partition wall 197 surrounding a side surface of the frame 191 and a side surface of the filling layer 195. In this case, an opening portion 194 can be formed in an upper portion of the partition wall 197. The opening portion 194 can expose a partial region of the upper surface of the filling layer 195. The opening portion 194 can overlap the light emitting chip 193. The partition wall 197 can be made of a material that reflects light and, accordingly, light incident on the partition wall 197 can be reflected from the inside of the opening portion 194 to be condensed in front of the display device. For example, a path of light emitted from the light emitting chip 193 can be controlled through the opening portion 194.

According to an embodiment, the shape of the opening 194 of the partition 197 can vary. For example, a plane of the opening 194 of the partition 197 of FIG. 12 can be implemented as a circular, rectangular, or semicircular combination. When the plane of the opening 194 is implemented by a combination of semicircles, at least a portion of the partition 197 can be further disposed in the center of the opening 194 of FIG. 12. In this case, the opening 194 can be disposed on both sides of the partition wall that is further disposed.

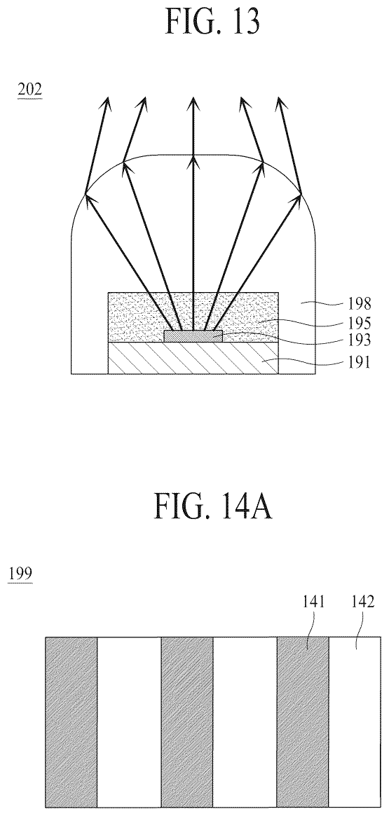

Referring to another example of FIG. 13, the second light emitting unit 202 can include a frame 191, a light emitting chip 193, a filling layer 195, and a lens 198. The frame 191, the light emitting chip 193, and the filling layer 195 of FIG. 12 are the same as those of FIG. 9, and thus a detailed description thereof will be omitted or may be briefly provided. With respect to the partition wall 198, the same contents as those of FIG. 10 can be omitted or may be briefly provided.

The second light emitting unit 202 of FIG. 13 can include a lens 198 surrounding a side surface of the frame 191 and an upper surface and a side surface of the filling layer 195. The lens 198 can have a convex shape. At least a portion of the lens 198 contacting the side surface of the frame 191 and the side surface of the filling layer 195 can have a predetermined thickness or more. Accordingly, the path of the light to the side surface can be restricted and condensing can be performed in front of the display device.

FIGS. 14A, 14B, and 14C illustrate three different examples of a louver of a display device according to an embodiment of the present disclosure. FIGS. 14A, 14B, and 14C are cross-sectional views of the louver 199. Any of the configurations of the louver of FIGS. 14A, 14B and 14C can be applied to any louver of the display device described in various examples of the present disclosure.

Referring to FIGS. 14A, 14B, and 14C, each louver 199 can be divided into a plurality of cells 142 alternatively disposed between a plurality of blocking films 141.

In FIGS. 14A and 14B, the blocking layer 141 of the louver 199 is disposed perpendicular to the lower side surface of the louver 199.

FIG. 14C illustrates an example in which the blocking film 141 of the louver 199 is disposed to have a predetermined angle with respect to the lower side surface of the louver 199. In the example of FIG. 14C, a portion of the blocking layers 141 of the louver 199 can be disposed at an angle different from an angle between another portion of the blocking layers 141 and the lower side of the louver 199. The blocking films 141 of the louver 199 can be disposed such that an upper side thereof is closer to the central axis C than a lower side thereof with respect to the central axis C of the louver 199. In this case, light incident to the louver 199 can be more easily concentrated in front of the display device.

Referring to FIG. 14C, an angle between the blocking layer 141 and the central axis C can correspond to a range greater than −40° and less than +40°. In an embodiment, an angle between each of the plurality of blocking layers 141 and the central axis C can be different for each blocking layer 141, but an angle between each of the blocking layers 141 and the central axis C can correspond to a range greater than −40° and less than +40°. For example, when the blocking layer 141 includes the first blocking layer and the second blocking layer, an angle between the first blocking layer and the central axis C can be 10°, and an angle between the second blocking layer and the central axis C can be 15°.

As a result, the light can be emitted from the second light emitting units 202 in a limited manner and direction, so that the light emitted from the second light emitting units 202 is directed towards the display panel 157 of the display device in a viewing angle limit mode. Accordingly, the contents displayed in the viewing angle limit mode (e.g., in the first region 1110) may be viewable by only a user located at a specific angle/location with respect to the screen. For instance, the contents displayed from the first region 1110 in the viewing angle limit mode may not be viewable by the driver in the vehicle but is viewable by the passenger in the vehicle at the same time.

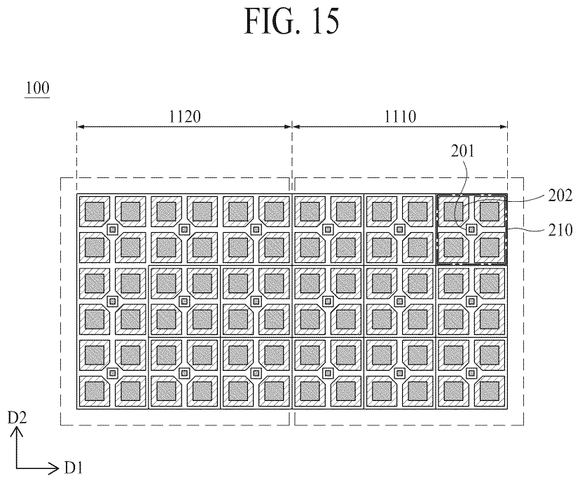

FIG. 15 illustrates an arrangement of light emitting units included in a display device according to another embodiment of the present disclosure. Particularly. FIG. 15 illustrates an example of a uniform arrangement of light emitting units in the light emitting package layer of a display device.

Referring to the example of FIG. 15, the first light emitting unit 201 and the second light emitting unit 202 can be disposed in the first region 1110 and the second region 1120. For example, the light emitting package 210 including the first light emitting unit 201 and the second light emitting unit 202 can be disposed, both in the first region 1110 and the second region 1120. The light emitting package 210 can be disposed to form a row in the first direction D1 and the second direction D2.

In this case, the position of the first region 1110 in the display area can be determined based on software control. For example, the second light emitting unit 202 included in the portion determined as the first region 1110 can be controlled to emit light as the first region 1110 is driven in a viewing angle limit mode. The first light emitting unit 201 included in the portion determined as the first region 1110 can be controlled not to emit light as the first region 1110 is driven in a viewing angle limit mode. The second light emitting unit 202 included in the portion determined as the second region 1120 can be controlled not to emit light as the second region 1120 is driven in a normal mode. For example, each of the first and second regions 1110 and 1120 can be selectively driven in a normal mode or a viewing angle limit mode, depending on the needs.

A display device according to an example configuration of the present disclosure includes a substrate, a light emitting package disposed in the first area on the substrate, the light emitting package including at least one first light emitting unit and a plurality of second light emitting units, at least one third light emitting unit disposed in a second area on the substrate, and a display panel disposed on the light emitting package and the at least one third light emitting unit. Also, the plurality of second light emitting units include a light emitting chip and a light control unit disposed on the light emitting chip.

In one configuration, the light control unit include at least one of a louver and a lens. The plurality of second light emitting units can include a frame disposed under the light emitting chip, the frame connected to the substrate, a filling layer covering the light emitting chip, and a partition wall surrounding a side surface of the frame and a side surface of the filling layer. Also, the light control unit can include the louver disposed on the filling layer, and a height of the partition wall can be greater than a sum of heights of the frame, the filling layer, and the louver

In one configuration, the louver includes a plurality of blocking layers and a plurality of cells divided by the plurality of blocking layers, and each of the plurality of blocking layers is disposed to have a predetermined angle with the light emitting chip.

In one configuration, the lens can have a convex shape. The light control unit includes the louver disposed on the light emitting chip and the lens disposed on the louver, and the path of light emitted from the light emitting chip can be changed by the louver and the lens.

In one configuration, the display device further includes a polarizing layer disposed under the display panel, a prism layer disposed under the polarizing layer, and a diffuser layer disposed under the prism layer.

In a configuration, the plurality of second light emitting units surround the at least one first light emitting unit. The plurality of second light emitting units includes a 2-1th light emitting unit, a 2-2th light emitting unit, a 2-3th light emitting unit, and a 2-4th light emitting unit, and the at least one first light emitting unit includes a 1-1th light emitting unit, and the 2-1th light emitting unit, the 2-2th light emitting unit, the 2-3th light emitting unit, and the 2-4th light emitting unit can be disposed around the 1-1th light emitting unit.

In an embodiment, the at least one first light emitting unit and the at least one third light emitting unit can include a light emitting chip, a filling layer disposed on the light emitting chip, and a reflective layer disposed on the filling layer.

In an example of the present disclosure, a display device includes a display panel configured to display images, and including a first region and a second region adjacent to the first region; and a light emitting package layer including a plurality of light emitting packages corresponding to the first region and a plurality of third light emitting units corresponding to the second region, wherein each of the plurality of light emitting packages includes at least one first light emitting unit and a plurality of second light emitting units, wherein the at least one first light emitting unit and the plurality of third light emitting units have a same configuration, and wherein each of the plurality of second light emitting units is configured to change a path of light in a viewing angle limit mode.

According to one or more aspects of the present disclosure, the following advantageous effects can be obtained.

According to one or more aspects of the present disclosure, a display device is provided in which a viewing angle is effectively limited or controlled.

According to one or more aspects of the present disclosure, a display device is provided where contents displayed by the display device is limited to a specific user, e.g., in a vehicle.

According to one or more aspects of the present disclosure, the plurality of light conversion layers can be formed so that light efficiency can be improved, and reflectance due to external light can be reduced.

It will be apparent to those skilled in the art that the present disclosure described above is not limited by the above-described embodiments and the accompanying drawings and that various substitutions, modifications and variations can be made in the present disclosure without departing from the spirit or scope of the disclosures. Consequently, the scope of the present disclosure is defined by the accompanying claims and it is intended that all variations or modifications derived from the meaning, scope and equivalent concept of the claims fall within the scope of the present disclosure.

What is claimed is:

1. A display device comprising:
a light emitting package disposed in a first area on a substrate, the light emitting package including at least one first light emitting unit and a plurality of second light emitting units;
at least one third light emitting unit disposed in a second area on the substrate, the second area being adjacent to the first area; and
a display panel disposed on the light emitting package and the at least one third light emitting unit,
wherein each of the plurality of second light emitting units includes a light emitting chip and a light control unit disposed on the light emitting chip, and
wherein the light control unit is configured to change a path of light emitted from the light emitting chip.

2. The display device of claim 1, wherein the light control unit includes at least one of a louver and a lens.

3. The display device of claim 1, wherein each of the plurality of second light emitting units includes:
a frame disposed below the light emitting chip, the frame connected to the substrate,
a filling layer covering the light emitting chip, and
a partition wall surrounding a side surface of the frame and a side surface of the filling layer.

4. The display device of claim 3, wherein the light control unit includes a louver disposed on the filling layer, and
wherein a height of the partition wall is greater than a sum of a height of the frame, a height of the filling layer, and a height of the louver.

5. The display device of claim 3, wherein an opening is formed through a top portion of the partition wall to expose a top surface of the filling layer, and
wherein the opening functions as the light control unit to change the path of the light emitting from the light emitting chip.

6. The display device of claim 2, wherein the louver includes a plurality of blocking layers and a plurality of cells divided by the plurality of blocking layers, and
wherein each of the plurality of blocking layers is disposed to have a predetermined angle with the light emitting chip.

7. The display device of claim 2, wherein the lens has a convex shape.

8. The display device of claim 2, wherein the light control unit includes the louver disposed on the light emitting chip and the lens disposed on the louver, and
wherein the path of light emitted from the light emitting chip is changed by the louver and the lens.

9. The display device of claim 1, further comprising:
a polarizing layer disposed below the display panel;
a prism layer disposed below the polarizing layer; and
a diffuser layer disposed below the prism layer.

10. The display device of claim 9, further comprising a cover glass disposed on the display panel.

11. The display device of claim 2, wherein the plurality of second light emitting units surround the at least one first light emitting unit in the first area on the substrate.

12. The display device of claim 11, wherein the plurality of second light emitting units include a 2-1th light emitting unit, a 2-2th light emitting unit, a 2-3th light emitting unit, and a 2-4th light emitting unit,
the at least one first light emitting unit includes a 1-1-th light emitting unit, and
the 2-1th light emitting unit, the 2-2th light emitting unit, the 2-3th light emitting unit, and the 2-4th light emitting unit are disposed around the 1-1 light emitting unit.

13. The display device of claim 1, wherein each of the at least one first light emitting unit and the at least one third light emitting unit include a light-emitting chip, a filling layer disposed on the light emitting chip, and a reflective layer disposed on the filling layer.

14. A vehicle comprising:
an interior part disposed inside the vehicle; and
the display device of claim 1 and being disposed at the interior part of the vehicle.

15. A display device comprising:
a display panel configured to display images, and including a first region and a second region adjacent to the first region; and
a light emitting package layer including a plurality of light emitting packages corresponding to the first region and a plurality of third light emitting units corresponding to the second region,
wherein each of the plurality of light emitting packages includes at least one first light emitting unit and a plurality of second light emitting units,
wherein the at least one first light emitting unit and the plurality of third light emitting units have a same configuration, and
wherein each of the plurality of second light emitting units is configured to change a path of light in a viewing angle limit mode.

16. The display device of claim 15, wherein each of the plurality of second light emitting units includes a light emitting chip and a light control unit disposed on the light emitting chip, and
wherein the path of the light emitted from the light emitting chip is changed by the light control unit in the viewing angle limit mode.

17. The display device of claim 16, wherein the light control unit includes at least one of a louver and a lens, and
wherein the louver includes a plurality of blocking layers and a plurality of cells divided by the plurality of blocking layers.

18. The display device of claim 15, wherein in each of the plurality of light emitting packages, four second light emitting units are disposed to surround the first light emitting unit.

19. The display device of claim 15, wherein a plurality of the first light emitting units corresponding to the first region and the plurality of third light emitting units corresponding to the second region are disposed in a matrix manner with a same distance therebetween, and
wherein the plurality of second light emitting units corresponding to the first region are disposed in rows and columns, and surround each of the first light emitting units.

20. A vehicle comprising:
an interior part disposed inside the vehicle; and
the display device of claim 15 and being disposed at the interior part,
wherein during the viewing angle limit mode, a driver in a driver's seat of the vehicle is unable to view contents displayed in the first region of the display device while a passenger in a passenger's seat of the vehicle is able to view the contents displayed in the first region of the display device.
